(19) United States
(12) Patent Application Publication
(10) Pub. No.: US 2024/0417846 A1
(43) Pub. Date: Dec. 19, 2024

(54) Fe-Pt-C-BASED SPUTTERING TARGET MEMBER, SPUTTERING TARGET ASSEMBLY, METHOD FOR FORMING FILM, AND METHOD FOR PRODUCING SPUTTERING TARGET MEMBER

(71) Applicant: JX Metals Corporation, Minato-ku, Tokyo (JP)

(72) Inventors: Takashi Kosho, Ibaraki (JP); Yusuke Horie, Ibaraki (JP)

(21) Appl. No.: 18/703,899

(22) PCT Filed: Sep. 22, 2022
(86) PCT No.: PCT/JP2022/035491

§ 371 Date: Apr. 23, 2024

(30) Foreign Application Priority Data
Nov. 5, 2021 (JP) 2021-181297

(51) Int. Cl. C23C 14/34

(52) U.S. Cl. CPC C23C 14/3414

(57) ABSTRACT

A Fe—Pt—C based sputtering target member that can suppress the generation of particles during sputtering is provided. A Fe—Pt—C based sputtering target member has a magnetic phase comprising Fe and Pt and a non-magnetic phase including C, wherein in an X-ray diffraction profile obtained by analyzing the sputtering target member by an X-ray diffraction method, the sputtering target member has a carbon-derived diffraction peak at a diffraction angle that satisfies 25.6°≤2θ≤26.2°.

### FIELD OF THE INVENTION

The present invention, in one embodiment, is related to a Fe—Pt—C based sputtering target member. In another embodiment, the invention is related to a sputtering target assembly comprising such a sputtering target member. In yet another embodiment, the present invention is related to a method for forming a film using such a sputtering target member. In yet another embodiment, the present invention is related to a method for manufacturing a sputtering target member.

### BACKGROUND OF THE INVENTION

In the field of magnetic recording, typified by hard disk drives, materials based on ferromagnetic metals such as Co, Fe, or Ni are used as materials for magnetic thin films responsible for recording. For example, Co—Cr-based or Co—Cr—Pt based ferromagnetic alloys containing Co as a main component have been used for the recording layer of hard disks employing a longitudinal magnetic recording method. In addition, the recording layer of a hard disk that uses a perpendicular magnetic recording method, which has been put into practical use in recent years, often uses composite materials made by dispersing non-magnetic particles such as oxides and carbon in a Co—Cr—Pt ferromagnetic alloy whose main component is Co. Magnetic thin films are often produced by sputtering a sputtering target member containing the above-mentioned materials using a DC magnetron sputtering device, due to its high productivity.

On the other hand, the recording density of hard disks is rapidly increasing year by year, and hard disks with capacities exceeding 1 T bit/in² are emerging on the market. When the recording density reaches 1 T bit/in², the size of the recording bit will become less than 10 nm, and in that case, it is expected that superparamagnetization due to thermal fluctuation will become a problem, and it is expected that the materials currently used for magnetic recording media, such as materials in which Pt is added to a Co—Cr based alloy to increase the magnetocrystalline anisotropy, are not sufficient. This is because magnetic particles that stably behave as ferromagnets with a size of 10 nm or less need to have even higher magnetocrystalline anisotropy.

For the reasons mentioned above, Fe—Pt magnetic phase having the L1₀ structure is attracting attention as a material for ultra-high density recording media. The Fe—Pt magnetic phase with the L1₀ structure has high magnetocrystalline anisotropy as well as excellent corrosion resistance and oxidation resistance, so it is expected to be a material suitable for application as a magnetic recording medium. Further, when using the Fe—Pt magnetic phase as a material for ultra-high density recording media, there is a need for the development of a technique for dispersing ordered Fe—Pt magnetic particles in a magnetically isolated state as densely as possible with the orientation aligned.

For these reasons, a granular structure magnetic thin film in which a Fe—Pt magnetic phase with an L1₀ structure is isolated with non-magnetic materials such as oxides, nitrides, carbides, and carbon has been proposed for use as a magnetic recording medium for next-generation hard disks employing a thermally assisted magnetic recording method. This granular structure magnetic thin film has a structure in which magnetic particles are magnetically insulated from each other by the presence of a non-magnetic substance.

However, when trying to sputter a sputtering target member whose alloy contains a non-magnetic material with a sputtering device, there is a problem in that during sputtering, abnormal discharge occurs starting from unexpected detachment of the non-magnetic material or pores included in the sputtering target member, and particles are generated. In particular, when carbon is used as a non-magnetic material, there is a problem in that carbon is a material that is difficult to sinter, and that carbon particles tend to form aggregates with each other. Therefore, there is a problem that carbon lumps are easily detached during sputtering, and many particles are generated on the film after sputtering.

To solve this problem, Patent Literature 1 (Japanese Patent No. 5497904) discloses a sputtering target member for a magnetic recording film, characterized in that when a crystallinity of a carbon material is evaluated by Raman scattering spectroscopy and vibration modes called G band and D band are measured, a peak intensity ratio (I_{G}/I_{D}) of the G band and D band is 5.0 or less. On the contrary, Patent Literature 2 (Japanese Patent No. 5592022) discloses a sputtering target member for a magnetic recording film, characterized in that the peak intensity ratio (I_{G}/I_{D}) of G band and D band is 5.0 or more.

### PRIOR ART

### Patent Literature

[Patent Literature 1] Japanese Patent No. 5497904
[Patent Literature 2] Japanese Patent No. 5592022

### SUMMARY OF THE INVENTION

According to the techniques described in the above patent literatures, it is possible to reduce the generation of particles when sputtering a Fe—Pt—C based sputtering target member. However, for Fe—Pt—C based sputtering target members, providing a different approach to suppress particles would be useful in expanding the possibilities for future technological development in this technical field.

Therefore, in one embodiment of the present invention, it is an object to provide a Fe—Pt—C based sputtering target member that can suppress the generation of particles during sputtering using a method different from the conventional methods. In another embodiment of the present invention, it is an object to provide a sputtering target assembly comprising such a sputtering target member. In yet another embodiment of the present invention, it is an object to provide a method for forming a film using such a sputtering target member. In yet another embodiment of the present invention, it is an object to provide a method for manufacturing such a Fe—Pt—C based sputtering target member.

The inventors of the present invention have made extensive studies to solve the above problems and have discovered that, a Fe—Pt—C based sputtering target member that contains carbon with a diffraction peak (peak top) at a diffraction angle shifted from normal graphite in structural analysis using an X-ray diffraction method is effective in reducing the number of particles. The present invention was completed based on this knowledge, and is exemplified as below.

[1]

A Fe—Pt—C based sputtering target member having a magnetic phase comprising Fe and Pt and a non-magnetic phase comprising C, wherein in an X-ray diffraction profile obtained by analyzing the sputtering target member by an X-ray diffraction method, the sputtering target member has a carbon-derived diffraction peak at a diffraction angle that satisfies 25.6°≤2θ≤26.20.

[2]

The Fe—Pt—C based sputtering target member according to [1], wherein in the X-ray diffraction profile obtained by analyzing the sputtering target member by the X-ray diffraction method, a ratio of an integrated intensity I₀ at a diffraction angle in a range of 26.3°≤2θ≤27.0° to an integrated intensity I₁ at the diffraction angle in a range of 25.6°≤2θ≤26.2° is 0 to 0.5.

[3]

The Fe—Pt—C based sputtering target member according to [1] or [2], comprising 5 at. % to 70 at. % of Pt, 1 at. % to 70 at. % of C, wherein a total concentration of Fe, Pt, and C is 90 at. % or more.

[4]

The Fe—Pt—C based sputtering target member according to [1] or [2], comprising 5 at. % to 70 at. % of Pt, 1 at. % to 70 at. % of C, the remainder consisting of Fe and unavoidable impurities.

[5]

A sputtering target assembly, comprising the sputtering target member according to any one of [1] to [4], and a backing tube or a backing plate bonded to the sputtering target member.

[6]

A method for forming a film, comprising sputtering the sputtering target member according to any one of [1] to [4].

[7]

A method for manufacturing a sputtering target member, comprising:
preparing a mixed powder comprising one or both of the following combinations (1) and (2):
   (1) a combination of: one or both selected from graphene powder and graphene oxide powder; and Fe—Pt alloy powder;
   (2) a combination of: one or both selected from graphene powder and graphene oxide powder; and Fe powder and Pt powder; and
pressure sintering the mixed powder.

By sputtering using the Fe—Pt—C based sputtering target member according to an embodiment of the present invention, it is possible to suppress the generation of particles during sputtering. By using the sputtering target member according to an embodiment of the present invention, a significant effect can be obtained that, for example, the manufacturing yield of a granular structure magnetic thin film having a Fe—Pt magnetic phase can be improved.

### DETAILED DESCRIPTION OF THE INVENTION

### (1. Magnetic Phase)

A sputtering target member according to one embodiment of the present invention has a magnetic phase comprising Fe and Pt. In the magnetic phase, Fe and Pt can be present alone or in the form of a Fe—Pt alloy. The magnetic phase may contain other alloying elements. In one embodiment, the magnetic phase comprising Fe and Pt may have a composition of 5 to 70 at. % Pt, the remainder consisting of Fe and unavoidable impurities. It is also possible to have a composition comprising 5 to 60 at. % of Pt, the remainder consisting of Fe and unavoidable impurities. Further, in another embodiment, the magnetic phase comprising Fe and Pt may have a composition comprising 5 to 70 at. % of Pt, a total of 20 at. % or less of one or more third elements selected from Ge, Au, Ag, B, Co, Cr, Cu, Mn, Mo, Nb, Ni, Pd, Re, Rh, Ru, Sn, Ta, W, V and Zn, and the remainder consisting of Fe and unavoidable impurities. It is also possible to have a composition comprising 5 to 60 at. % of Pt, a total of 20 at. % or less of one or more third elements selected from Ge, Au, Ag, B, Co, Cr, Cu, Mn, Mo, Nb, Ni, Pd, Re, Rh, Ru, Sn, Ta, W, V and Zn, and the remainder consisting of Fe and unavoidable impurities.

From the viewpoint that the magnetic phase comprising Fe and Pt easily takes the form of an ordered alloy phase, the atomic concentration of Pt in the magnetic phase is preferably 35 at. % or more, more preferably 40 at. % or more, and even more preferably 45 at. % or more. In addition, for the same reason, the atomic concentration of Pt in the magnetic phase is preferably 55 at. % or less, more preferably 53 at. % or less, and even more preferably 52 at. % or less.

Further, Ge, Au, Ag, B, Co, Cr, Cu, Mn, Mo, Nb, Ni, Pd, Re, Rh, Ru, Sn, Ta, W, V, and Zn may be initiatively added, because they have an effect of lowering the heat treatment temperature for ordering the magnetic phase comprising Fe and Pt, and may also have other effects, such as increasing the magnetocrystalline anisotropy energy and coercive force. From the viewpoint of significantly exhibiting such effect, the concentration of these third elements contained in the magnetic phase is preferably 1 at. % or more in total, more preferably 2.5 at. % or more in total, and even more preferably 5 at. % or more in total. In addition, from the viewpoint of obtaining sufficient magnetic properties as a magnetic thin film when sputtered, the concentration of these third elements in the magnetic phase is preferably 20 at. % or less in total, more preferably 15 at. % or less in total, and even more preferably 10 at. % or less in total. In addition, these third elements can exist not only in the magnetic phase, but also as a single phase separate from the magnetic phase. Whether the third elements exist in the magnetic phase comprising Fe and Pt or as a single phase can be determined by performing elemental mapping using EPMA or the like.

For the same reason as above, the total concentration of these third elements in the sputtering target member, including cases where these third elements exist in the Fe—Pt alloy phase and cases where they exist as a single phase, is preferably 0.5 at. % or more, more preferably 2 at. % or more, and even more preferably 4 at. % or more. Further, for the same reason as above, the total content of these third elements in the sputtering target member is preferably 15 at. % or less, more preferably 12.5 at. % or less, and even more preferably 10 at. % or less.

### (2. Non-Magnetic Phase)

A sputtering target member according to one embodiment of the present invention has a non-magnetic phase containing C (carbon). The non-magnetic phase can exist in a dispersed state in the above-mentioned magnetic phase comprising Fe and Pt. C constituting the non-magnetic phase has a characteristic crystal structure. As a result, in an X-ray diffraction profile obtained by analyzing the sputtering target member by an X-ray diffraction method, the sputtering target member has a carbon-derived diffraction peak at a diffraction angle that satisfies 25.6°≤2θ≤26.2°, typically, 25.8°≤2θ≤26.0°. Having a diffraction peak within the range of the diffraction angle suppresses particles during sputtering.

In the X-ray diffraction profile obtained by analyzing graphite using the X-ray diffraction method, diffraction peaks are seen at diffraction angles in the range of 26.3°≤2θ≤27.0°. However, the sputtering target member according to the present embodiment contains C whose diffraction peak is shifted to the lower angle side. Therefore, it can be said that in the sputtering target member according to this embodiment, the crystal structure of C constituting the non-magnetic phase is different from that of normal graphite. Examples of graphite include exfoliated graphite, expanded graphite, vein graphite, flake graphite, and the like.

The sputtering target member according to one embodiment of the present invention may partially contain graphite, but preferably in a small amount. Specifically, as for the sputtering target member according to one embodiment of the present invention, in the X-ray diffraction profile obtained by analyzing the sputtering target member by the X-ray diffraction method, the ratio of the integrated intensity I₀ at the diffraction angle in the range of 26.3°≤2θ≤27.0° to the integrated intensity I₁ at the diffraction angle in the range of 25.6°≤2θ≤26.2° is 0 to 0.5, typically 0 to 0.2, more typically 0 to 0.1, and even more typically 0.

In the present invention, the method for analyzing the structure of a sputtering target member by X-ray diffraction is as follows.

Analyzing device: X-ray diffraction device (in the Examples, a fully automatic horizontal multipurpose X-ray diffraction device SmartLab manufactured by Rigaku Corporation was used)
Tube: Cu (measured with CuKα)
Tube voltage: 40 kV
Tube current: 30 mA
Optical system: Focused diffraction optical system
Scan mode: 2θ/θ
Scanning range (2θ): 10° to 90°
Measurement step (2θ): 0.02°
Scan speed (2θ): 0.5° per minute
Attachment: Standard attachment
Filter: CuKβ filter
Counter monochrome: None
Counter: D/teX Ultra
Divergence slit: ⅔ deg.
Divergent vertical slit: 10.0 mm
Scattering slit: 10.0 mm
Light receiving slit: 10.0 mm
Attenuator: OPEN
Measurement sample size: Approximately 20 mm×15 mm (measurement surface)

The analysis may be performed on any measurement surface of the sputtering target member. For example, it may be a sputtering surface, a cross section parallel to the sputtering surface, or a cross section perpendicular to the sputtering surface. Further, the measurement surface is polished using coated abrasive with a grit of P80 to P2000 based on the FEPA standard in this order, and finally buffed using aluminum oxide abrasive grains with a grain size of about 0.3 μm. In Examples, the obtained XRD profile was analyzed using integrated powder X-ray analysis software PDXL (version 1.6.0.0) available from Rigaku Corporation. Here, a peak search was performed using automatic profile processing on the obtained measurement data, and the peak position and integrated intensity were calculated.

In the peak search, the measured data is subjected to background removal, Kα₂ removal, and smoothing in this order, and then peaks are detected using the second-order differential method. In the process using the second-order differential method, peaks whose intensity is not considered to be sufficiently large relative to the error are discarded and are not detected as peaks. Further, the peak shape is expressed by a divided pseudo-Voigt function, and the peak position, half-width, integrated intensity, and the like can be calculated.

The methods and conditions for each process in the peak search are shown below.

Background removal: method using polynomial fitting (peak width threshold 1.00, intensity threshold 10.00)

Kα₂ removal: Rachinger method (intensity ratio 0.5)

Smoothing: B-spline smoothing method (smoothing parameter 10.00, number of points 3, x threshold 1.5)

From the peak search results, the presence or absence of a diffraction peak in the range of 25.6°≤2θ≤26.2° is investigated.

The sputtering target member according to one embodiment of the present invention may comprise, as a non-magnetic material, at least one or two or more selected from carbides, oxides, nitrides, and carbonitrides, in addition to C. The non-magnetic material can be present in a dispersed state in the sputtering target member as a non-magnetic phase that is distinguishable from the Fe—Pt alloy phase. Examples of carbides include carbides of one or more elements selected from B, Ca, Nb, Si, Ta, Ti, W, and Zr. Examples of oxides include oxides of one or more elements selected from Si, Al, B, Ba, Be, Ca, Ce, Cr, Dy, Er, Eu, Ga, Gd, Ho, Li, Mg, Mn, Nb, Nd, Pr, Sc, Sm, Sr, Ta, Tb, Ti, V, Y, Zn and Zr. Examples of nitrides include nitrides of one or more elements selected from B, Al, Ca, Nb, Si, Ta, Ti, and Zr. Examples of carbonitrides include carbonitrides of one or more elements selected from Ti, Cr, V, and Zr. These non-magnetic materials may be added as appropriate depending on the required magnetic properties of the magnetic thin film.

### (3. Overall Composition)

A sputtering target member according to an embodiment of the present invention comprises 5 at. % to 70 at. % of Pt and 1 at. % to 70 at. % of C. A sputtering target member according to another embodiment of the present invention comprises 10 at. % to 60 at. % of Pt and 2 at. % to 60 at. % of C. A sputtering target member according to yet another embodiment of the present invention comprises 20 at. % to 50 at. % of Pt and 5 at. % to 50 at. % of C. A sputtering target member according to yet another embodiment of the present invention comprises 20 at. % to 40 at. % of Pt and 30 at. % to 50 at. % of C. In each of the above embodiments, the total concentration of Fe, Pt, and C may be 90 at. % or more, 95 at. % or more, 98 at. % or more, or 99 at. % or more.

In each of the embodiments described above, there is no upper limit to the total concentration of Fe, Pt, and C, and the sputtering target member can be composed only of Fe, Pt, and C, other than unavoidable impurities. Therefore, the sputtering target member according to one embodiment of the present invention comprises 5 at. % to 70 at. % of Pt, 1 at. % to 70 at. % of C, and the remainder consists of Fe and unavoidable impurities. The sputtering target member according to another embodiment of the present invention comprises 10 at. % to 60 at. % of Pt, 2 at. % to 60 at. % of C, and the remainder consists of Fe and unavoidable impurities. The sputtering target member according to yet another embodiment of the present invention comprises 20 at. % to 50 at. % of Pt, 5 at. % to 50 at. % of C, and the remainder consists of Fe and unavoidable impurities. The sputtering target member according to yet another embodiment of the present invention comprises 20 at. % to 40 at. % of Pt, 30 at. % to 50 at. % of C, and the remainder consists of Fe and unavoidable impurities.

In each of the above embodiments, examples of elements other than Fe, Pt and C that may be added to the sputtering target member include one or more third elements selected from Ge, Au, Ag, B, Co, Cr, Cu, Mn, Mo, Nb, Ni, Pd, Re, Rh, Ru, Sn, Ta, W, V and Zn as mentioned above, as well as one or more selected from carbides, oxides, nitrides, and carbonitrides.

### (4. Relative Density)

In one embodiment of the sputtering target member according to the present invention, the relative density is preferably 80% or more, more preferably 85% or more, and even more preferably 90% or more. The relative density can be, for example, 80% to 95%, or even 80% to 90%. As used herein, the relative density is a value obtained by dividing the actually measured density of the sputtering target member by the calculated density (also referred to as the theoretical density). The actually measured density is measured by the Archimedes method. The calculated density is the density when it is assumed that the constituent components of the raw material powder of the target member are mixed without diffusing or reacting with each other, and is calculated by the following formula.

calculated density=Σ (molecular weight of constituent components of raw material powder×molar concentration of constituent components of raw material powder)/Σ (molecular weight of constituent components of raw material powder×molar concentration of constituent components of raw material powder/literature density value of constituent components of raw material powder) Formula:

Here, Σ means taking the sum of all constituent components other than impurities of the target member.

### (5. Manufacturing Method)

A sputtering target member according to one embodiment of the present invention can be manufactured using a powder sintering method, for example, by the following method. First, as metal powder, Fe powder, Pt powder, Pt—Fe alloy powder, optionally a third element powder, and the like are prepared. The third element powder may be provided in the form of an alloy powder with Fe and/or Pt. These metal powders may be produced by pulverizing melted and cast ingots, or may be produced as atomized powder.

Further, as the non-magnetic material powder, in addition to carbon powder, carbide powder, nitride powder, oxide powder, carbonitride powder, etc. are prepared as necessary. At this time, it is preferable to use graphene powder or graphene oxide powder as the carbon powder.

Next, the raw material powders (metal powder and non-magnetic material powder) are weighed so as to have a desired composition, and mixed while also being pulverized using a known method such as a ball mill. In this way, a mixed powder containing one or both of the following combinations (1) and (2) is prepared:
(1) a combination of: one or both selected from graphene powder and graphene oxide powder; and Fe—Pt alloy powder;
(2) a combination of: one or both selected from graphene powder and graphene oxide powder; and Fe powder and Pt powder.

At this time, it is desirable to suppress oxidation of the raw material powder as much as possible by sealing an inert gas in the pulverizing container. Examples of the inert gas include Ar and N₂ gas.

From the viewpoint of realizing a uniform structure, the median diameter (D50) in the volume-based particle size distribution of the raw material mixed powder is preferably 20 μm or less, more preferably 10 μm or less, and even more preferably 5 μm or less. On the other hand, from the viewpoint of suppressing compositional changes due to oxidation of the raw material mixed powder, the median diameter is preferably 0.3 μm or more, more preferably 0.5 μm or more, and even more preferably 1.0 μm or more.

In the present invention, the median diameter of the raw material mixed powder means the particle diameter at an integrated value of 50% (D50) on a volume basis in the particle size distribution determined by laser diffraction/scattering method. In the Examples, a particle size distribution analyzing device model LA-920 manufactured by HORIBA, Ltd. was used. The powder was dispersed in an ethanol solvent to perform measurements. For the refractive index, the value of metal platinum was used.

The mixed powder thus obtained is molded and sintered by a hot pressing method in a vacuum atmosphere or an inert gas atmosphere. In addition to the hot pressing method, various pressure sintering methods such as a plasma discharge sintering method can be used. In particular, hot isostatic pressing (HIP) is effective in increasing the density of sintered bodies, and it is preferable to carry out the hot pressing method and the hot isostatic pressing (HIP) method in this order from the viewpoint of improving the density of the sintered body.

The holding temperature during sintering may be appropriately set depending on the composition of the sputtering target member, but in order to prevent coarsening of crystal grains, it is preferably 1500° C. or lower, more preferably 1400° C. or lower, and even more preferably 1200° C. or lower. Further, in order to improve the density of the sintered body, the holding temperature during sintering is preferably 600° C. or higher, more preferably 700° C. or higher, and even more preferably 750° C. or higher.

In order to promote sintering, the pressing pressure during sintering is preferably 20 MPa or more, more preferably 25 MPa or more, and even more preferably 30 MPa or more. In addition, considering the strength of the die, the pressing pressure during sintering is preferably 70 MPa or less, more preferably 50 MPa or less, and even more preferably 40 MPa or less.

In order to improve the density of the sintered body, the sintering time is preferably 0.3 hours or more, more preferably 0.5 hours or more, and even more preferably 1.0 hours or more. In addition, in order to prevent coarsening of crystal grains, the sintering time is preferably 5.0 hours or less, more preferably 4.0 hours or less, and even more preferably 3.0 hours or less.

By molding the obtained sintered body into a desired shape using a lathe or the like, a sputtering target member according to one embodiment of the present invention can be manufactured. The shape of the target is not particularly limited, but examples thereof include a flat plate shape (including a disk shape and a rectangular plate shape) and a cylindrical shape. The sputtering target member according to one embodiment of the present invention is particularly useful as a sputtering target member used for forming a granular structure magnetic thin film.

If necessary, the sputtering target member may be attached to a substrate such as a backing plate or a backing tube, and mounted in a sputtering apparatus as a sputtering target assembly. The sputtering target member may be mounted on a sputtering apparatus as a sputtering target without using a substrate.

### (6. Method for Forming Film)

In one embodiment, the present invention provides a method for forming a film comprising sputtering using the sputtering target member. Sputtering conditions can be set as appropriate. For example, a magnetic thin film having a granular structure can be formed using the method for forming a film.

### EXAMPLES

Hereinafter, Examples of the present invention are shown below along with Comparative Examples. However, the Examples and the Comparative Examples are provided to better understand the present invention and its advantages, and are not intended to limit the present invention.

### Example 1

### <Preparation of Sputtering Target Member>

Fe powder (nominal purity 99.9 at. %), Pt powder (nominal purity 99.9 at. %), and graphene powder were purchased as raw material powders, and were weighed so that the atomic ratio was Fe:Pt:C=30:30:40. Next, the weighed powder was put into a ball mill together with zirconia balls as a grinding medium, and mixed and pulverized in an Ar atmosphere. The volume-based particle size distribution of the raw material mixed powder after the pulverization was determined using a laser diffraction particle size distribution analyzer (manufacturer: HORIBA, Ltd., model: LA-920), and the median diameter was calculated to be 8.6 μm.

Next, the raw material mixed powder taken out from the media stirring mill was filled into a mold made of carbon, and sintered in a vacuum atmosphere using a hot pressing. Next, the sintered body taken out from the hot pressing mold was subjected to hot isostatic pressing (HIP). The hot pressing was carried out at a holding temperature of 700 to 1400° C. and a pressing pressure of 20 to 30 MPa for 1 to 2 hours. The hot isostatic pressing (HIP) after the hot pressing was performed for densification. The relative density of the obtained sintered body was 87.9%.

Next, each sintered body was cut into a shape with a diameter of 180.0 mm and a thickness of 5.0 mm using a lathe to obtain a disc-shaped sputtering target member.

### <Structural Analysis>

The sputtering surface of the sputtering target member obtained by the above manufacturing procedure was polished under the conditions described above. Then, the structure of the sputtering surface after polishing was analyzed using an X-ray diffraction device (XRD) model SmartLab manufactured by Rigaku Corporation under the conditions described above. As a result, it was found that there was a diffraction peak derived from carbon at a diffraction angle of 2θ=25.9°. Further, in the obtained X-ray diffraction profile, the ratio of the integrated intensity I₀ at the diffraction angle in the range of 26.3°≤2θ≤27.0° to the integrated intensity I₁ at the diffraction angle in the range of 25.6°≤2θ≤26.2° was 0. In addition, the structural analysis by XRD was also performed on a cross section perpendicular to the sputtering surface, but no difference was observed.

### <Film Formation Test>

The sputtering target member obtained by the above manufacturing procedure was mounted on a magnetron sputtering device (C-3010 sputtering system manufactured by Canon Anelva Corporation), and sputtering was performed. The sputtering conditions were an input power of 1 kW and an Ar gas pressure of 1.7 Pa. After performing pre-sputtering for a total of 2 hours, a film was formed on a 4-inch diameter silicon substrate for 20 seconds. Then, the number of particles (particle size: 0.09 to 3 μm) adhering to the substrate was measured using a particle counter (manufactured by KLA-Tencor, device name: Candela CS920). As a result, the number of particles detected was 60.

### Comparative Example 1

### <Preparation of Sputtering Target Member>

Raw material powder was prepared, mixed and pulverized under the same conditions as in Example 1, except that commercially available graphite powder was used as the carbon powder. The volume-based particle size distribution of the raw material mixed powder after pulverization was determined under the same conditions as in Example 1, and the median diameter was calculated to be 7.3 μm. Next, the raw material mixed powder taken out from the media stirring mill was subjected to hot pressing and HIP under the same conditions as in Example 1. The relative density of the sintered body was 92.7%. Next, each sintered body was cut into a shape with a diameter of 180.0 mm and a thickness of 5.0 mm using a lathe to obtain a disc-shaped sputtering target member.

### <Structural Analysis>

The sputtering surface of the sputtering target member obtained by the above manufacturing procedure was subjected to XRD analysis in the same manner as in Example 1. As a result, there was no carbon-derived diffraction peak in the diffraction angle range of 25.6°≤2θ≤26.2°. Instead, it was found to have a carbon-derived diffraction peak at a diffraction angle of 2θ=26.6°. In addition, in the obtained X-ray diffraction profile, the ratio of the integrated intensity I₀ at the diffraction angle in the range of 26.3°≤2θ≤27.0° to the integrated intensity I₁ at the diffraction angle in the range of 25.6°≤2θ≤26.2° could not be calculated because the denominator was 0.

### <Film Formation Test>

Sputtering was performed under the same conditions as in Example 1 using the sputtering target member obtained by the above manufacturing procedure. The number of particles detected was 200.

### Comparative Example 2

### <Preparation of Sputtering Target Member>

Raw material powder was prepared, mixed and pulverized under the same conditions as in Example 1, except that commercially available graphite powder (same graphite powder as in Example 4 of Japanese Patent No. 5592022) was used as the carbon powder. The volume-based particle size distribution of the raw material mixed powder after pulverization was determined under the same conditions as in Example 1, and the median diameter was calculated to be 25.5 μm. Next, the raw material mixed powder taken out from the media stirring mill was subjected to hot pressing and HIP under the same conditions as in Example 1. The relative density of the sintered body was 93.4%. Next, each sintered body was cut into a shape with a diameter of 180.0 mm and a thickness of 5.0 mm using a lathe to obtain a disc-shaped sputtering target member.

### <Structural Analysis>

The sputtering surface of the sputtering target member obtained by the above manufacturing procedure was subjected to XRD analysis in the same manner as in Example 1. As a result, there was no carbon-derived diffraction peak in the diffraction angle range of 25.6°≤2θ≤5 26.2°. Instead, it was found to have a carbon-derived diffraction peak at a diffraction angle of 2θ=26.6°. In addition, in the obtained X-ray diffraction profile, the ratio of the integrated intensity I₀ at the diffraction angle in the range of 26.3°≤2θ≤27.0° to the integrated intensity I₁ at the diffraction angle in the range of 25.6°≤2θ≤26.2° could not be calculated because the denominator was 0.

### <Film Formation Test>

Sputtering was performed under the same conditions as in Example 1 using the sputtering target member obtained by the above manufacturing procedure. The number of particles detected was 1000.

From the results of Example 1, Comparative Example 1, and Comparative Example 2, it can be seen that by using the Fe—Pt—C based sputtering target member having a carbon-derived diffraction peak at a predetermined diffraction angle, particles during sputtering could be significantly suppressed.

Comparative Example 2, which used carbon powder with a larger median diameter, had a larger number of particles during sputtering than Comparative Example 1. If this tendency is applied to Comparative Example 1 and Example 1, it is predicted that the number of particles during sputtering is about the same, or even smaller in Comparative Example 1. However, in reality, Example 1 was able to suppress the number of particles during sputtering more significantly than Comparative Example 1. This difference is considered to be due to the fact that the sputtering target member in Example 1 had a carbon-derived diffraction peak at a diffraction angle satisfying 25.6°≤2θ≤26.2°.

1. A Fe—Pt—C based sputtering target member having a magnetic phase comprising Fe and Pt and a non-magnetic phase comprising C, wherein in an X-ray diffraction profile obtained by analyzing the sputtering target member by an X-ray diffraction method, the sputtering target member has a carbon-derived diffraction peak at a diffraction angle that satisfies 25.6°≤2θ≤26.2°.

2. The Fe—Pt—C based sputtering target member according to claim 1, wherein in the X-ray diffraction profile obtained by analyzing the sputtering target member by the X-ray diffraction method, a ratio of an integrated intensity I₀ at a diffraction angle in a range of 26.3°≤2θ≤27.0° to an integrated intensity I₁ at the diffraction angle in a range of 25.6°≤2θ≤26.2° is 0 to 0.5.

3. The Fe—Pt—C based sputtering target member according to claim 1, comprising 5 at. % to 70 at. % of Pt, 1 at. % to 70 at. % of C, wherein a total concentration of Fe, Pt, and C is 90 at. % or more.

4. The Fe—Pt—C based sputtering target member according to claim 1, comprising 5 at. % to 70 at. % of Pt, 1 at. % to 70 at. % of C, the remainder consisting of Fe and unavoidable impurities.

5. A sputtering target assembly, comprising the sputtering target member according to claim 1, and a backing tube or a backing plate bonded to the sputtering target member.

6. A method for forming a film, comprising sputtering the sputtering target member according to claim 1.

7. A method for manufacturing a sputtering target member, comprising:
preparing a mixed powder comprising one or both of the following combinations (1) and (2):
(1) a combination of: one or both selected from graphene powder and graphene oxide powder; and Fe—Pt alloy powder;
(2) a combination of: one or both selected from graphene powder and graphene oxide powder; and Fe powder and Pt powder; and
pressure sintering the mixed powder.

8. The Fe—Pt—C based sputtering target member according to claim 2, comprising 5 at. % to 70 at. % of Pt, 1 at. % to 70 at. % of C, wherein a total concentration of Fe, Pt, and C is 90 at. % or more.

9. The Fe—Pt—C based sputtering target member according to claim 2, comprising 5 at. % to 70 at. % of Pt, 1 at. % to 70 at. % of C, the remainder consisting of Fe and unavoidable impurities.
